(19) United States
(12) Patent Application Publication
(10) Pub. No.: US 2011/0234068 A1
(43) Pub. Date: Sep. 29, 2011

(54) COMPUTER ENCLOSURE

(75) Inventor: CHIN-MING CHANG, Tu-Cheng (TW)

(73) Assignee: HON HAI PRECISION INDUSTRY CO., LTD., Tu-Cheng (TW)

(21) Appl. No.: 12/845,916

(22) Filed: Jul. 29, 2010

(30) Foreign Application Priority Data
Mar. 29, 2010 (TW) 99109459

(51) Int. Cl. H05K 5/03

(52) U.S. Cl. 312/309

(57) ABSTRACT

A computer enclosure includes a main body, the main body having a plurality of walls and defining an opening. One of the walls defines a plurality of first latching holes. A cover is detachably fixed with the main body for shielding the opening, and includes a plurality of first hooks for engaging in the corresponding latching holes, and two second hooks. A sliding member is slidable relative to the main body, and includes two latching portions for engaging the two second hooks, respectively. A rotating assembly is mounted on the cover, and includes a pivot rotatable relative to the cover, and a resisting member mounted securely around the pivot to move the sliding member along a predetermined direction. An elastic member is connected to the sliding member and the main body, respectively, for latching the two latching portions into the two second hooks.

### BACKGROUND

1. Technical Field

The present disclosure relates to an enclosure for a computer.

2. Description of Related Art

A typical computer enclosure includes a main body having several panels and an opening defined in a side thereof, and a detachable cover mounted on the main body for shielding the opening. The main body defines a cavity to receive a plurality of electronic components, such as a motherboard, and a hard disk. Generally, the cover is fixed on the main body by a plurality of screws or bolts. However, it is inconvenient for assembly or removal, because the screws or bolts must be screwed or unscrewed one by one. In addition, the computer enclosure may easily deform after multiple numbers of assembly or disassembly.

Therefore, there is room for improvement within the art.

### BRIEF DESCRIPTION OF THE DRAWINGS

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 is an assembled, isometric view of an embodiment of a computer enclosure.

FIG. 2 is an exploded, isometric view of the computer enclosure of FIG. 1.

FIG. 3 is a partial, exploded, isometric view of a main body and a sliding member of a computer enclosure, for example, that of FIG. 1.

FIG. 4 is similar to FIG. 3, but is viewed from another aspect.

FIG. 5 is a partial, exploded, isometric view of a rotating assembly and a main body of a computer enclosure, for example, that of FIG. 1.

FIG. 6 is an isometric view of the rotating assembly and the main body of FIG. 5.

FIG. 7 is a partial, assembled, isometric view of a main body and a sliding member of a computer enclosure, for example, that of FIG. 1.

FIG. 8 is a cross-sectional view of the computer enclosure, showing a latched state that a cover engages with a main body of a computer enclosure, for example, that of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

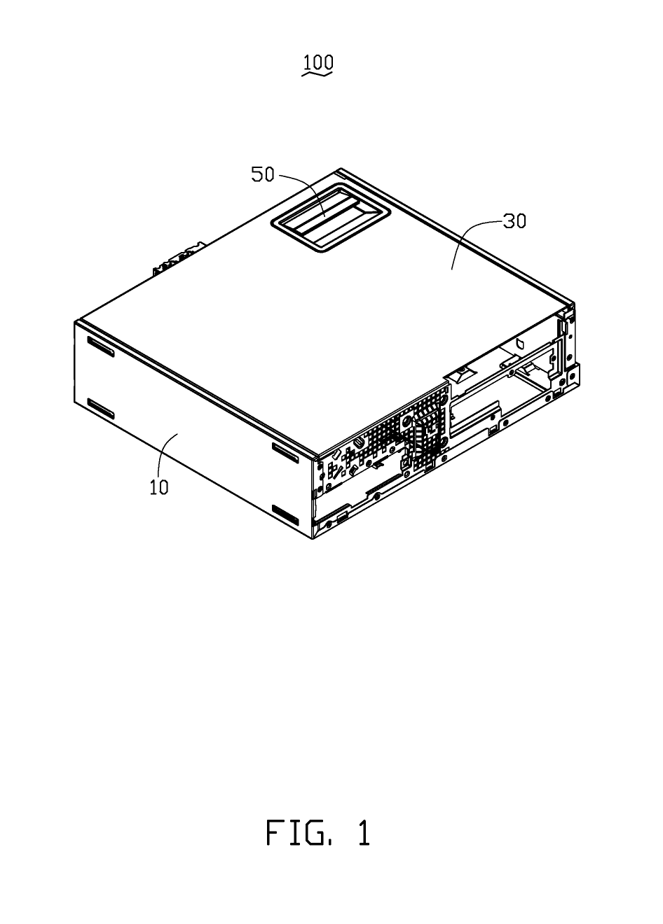

Referring to FIGS. 1 through 4, one embodiment of a computer enclosure 100 includes a main body 10, a cover 30, and a latching mechanism (not labeled) for releasably fixing the cover 30 to the main body 10.

The main body 10 includes a first sidewall 16, a second sidewall 18 opposite to the first sidewall 16, a third sidewall 22, a fourth sidewall 24 opposite to the third sidewall 22, and a bottom wall 26. The sidewalls 16, 18, 22, 24 and the bottom wall 26 cooperatively define an opening 28 on which the cover 30 is fixed. The main body 10 further includes a first assembly plate 12 mounted on the outside of the first sidewall 16, and a second assembly plate 14 mounted on the outside of the second sidewall 18.

The first sidewall 16 includes a guard 164 formed in the center, and two guiding posts 162 located on opposite sides of the guard 164, respectively. Each guiding post 162 defines a threaded hole 1621 for engaging with a bolt 1634. The guard 164 is provided with a through hole 1642 and a protection plate 1644 extending along a curve from an edge of the through hole 1642 to the opposite edge thereof.

The second sidewall 18 defines a plurality of latching holes 181 in the side adjacent to the opening 28. The plurality of latching holes 181 are arranged at a predetermined interval.

The cover 30 has a plurality of first hooks 32 formed on a first side, two second hooks 34 on a second side opposite to the first side, and a receiving portion 38 adjacent to a portion of the second side on which the second hooks 34 are formed. The first hooks 32 correspond to the latching holes 181 in the second sidewall 18. Each second hook 34 includes a support portion 342 and a hooking portion 344. The hooking portion 344 inward extends from an end of the support portion 342. The hooking portion 344 has an inclined abutting surface (not labeled).

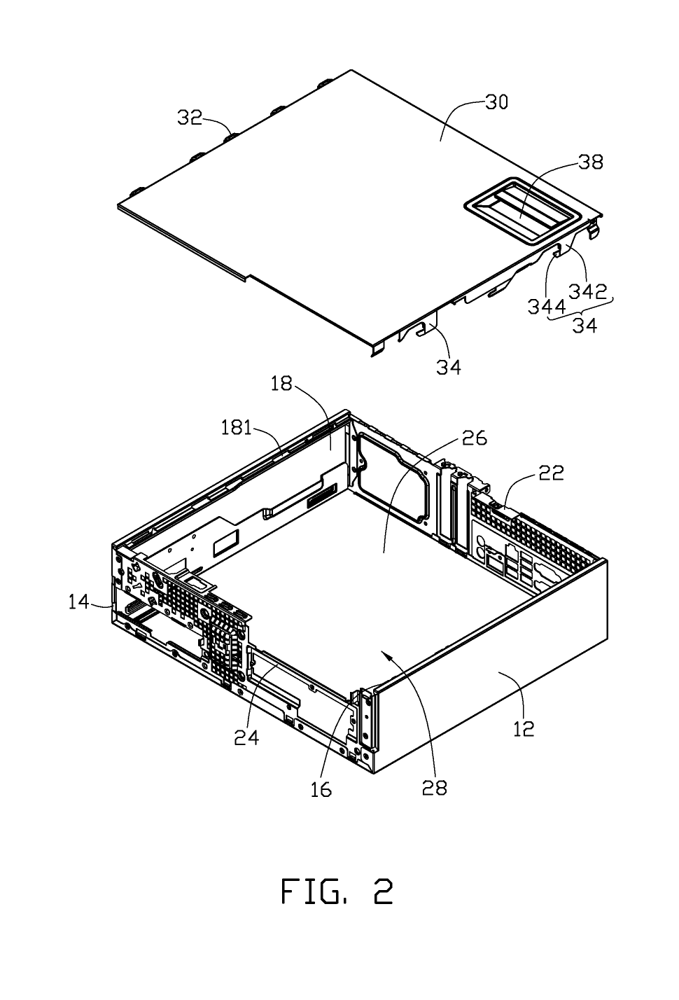

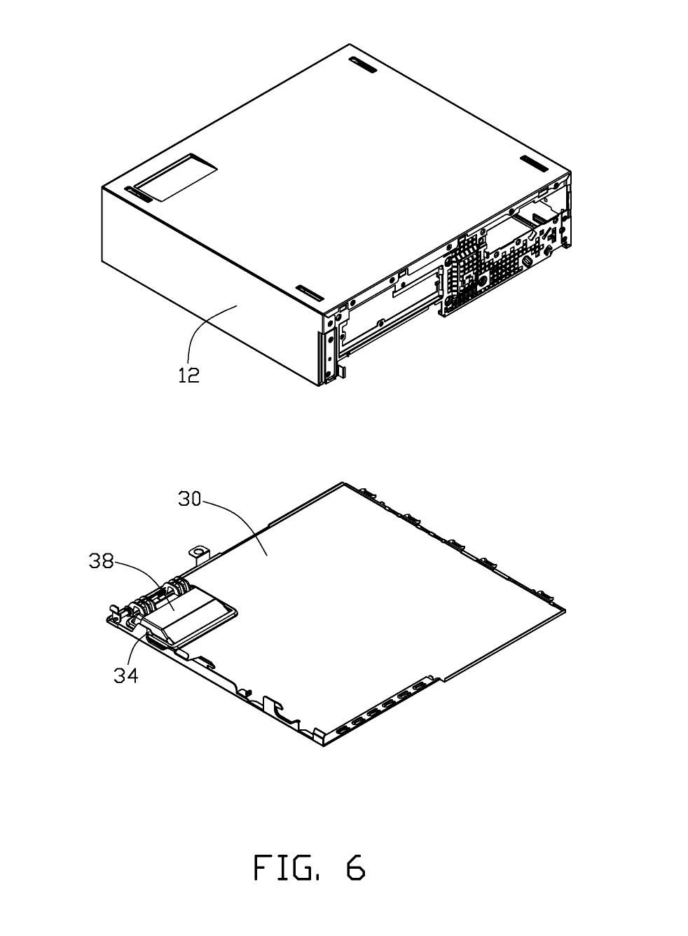

Referring to FIGS. 2, 5 and 6, the receiving portion 38 is a depressed portion extending downwards from the cover 30. The receiving portion 38 defines two assembly holes 382. The cover 30 defines two pivot holes 384 coaxial to each other in the inner surface.

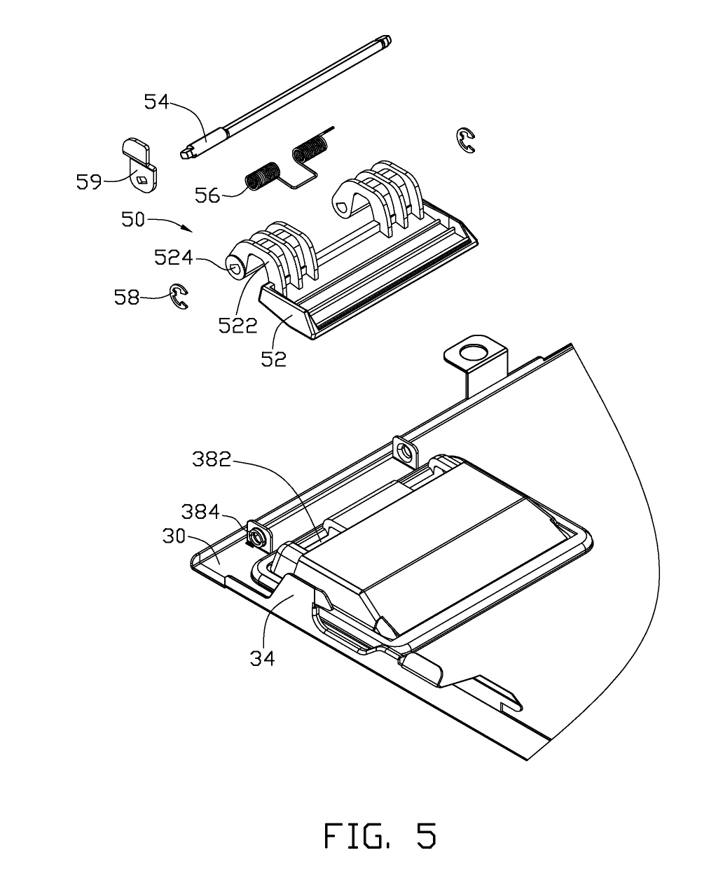

Referring to FIGS. 5 through 8, the latching mechanism includes a rotating assembly 50, a sliding member 70 mounted on a side of the first sidewall 16, and an elastic member 90 connecting the sliding member 70 and the first sidewall 16.

The rotating assembly 50 includes an operating member 52 received in the receiving portion 38, a pivot 54, a torsion spring 56, two clips 58, and a resisting member 59. The operating member 52 has two deformed flanges 522 formed on opposite sides, each of which defines a D shaped hole 524 for receiving the rotational pivot 54. The two deformed flanges 522 extend respectively into the two assembly holes 382. During assembly of the rotating assembly 50, the torsion spring 56 is located between the two flanges 522 for biasing the operating member 52. The operating member 52 and the torsion spring 56 are securely mounted around the rotational pivot 54. Opposite ends of the pivot 54 are rotatably received respectively in the two holes 524. Two C-shaped clips 58 are securely mounted on opposite ends of the pivot 54 to prevent the rotational pivot 54 from falling off. The resisting member 59 is a substantially rectangular sheet, and is securely mounted around the rotational pivot 54 for abutting the sliding member 70. When an external force rotates the operating member 52, the resisting member 59 rotates together with the rotational pivot 54 to move the sliding member 70 along a latitudinal direction. When the external force is withdrawn, the operating member 52 is capable of restoring to an original position via the torsion spring 56.

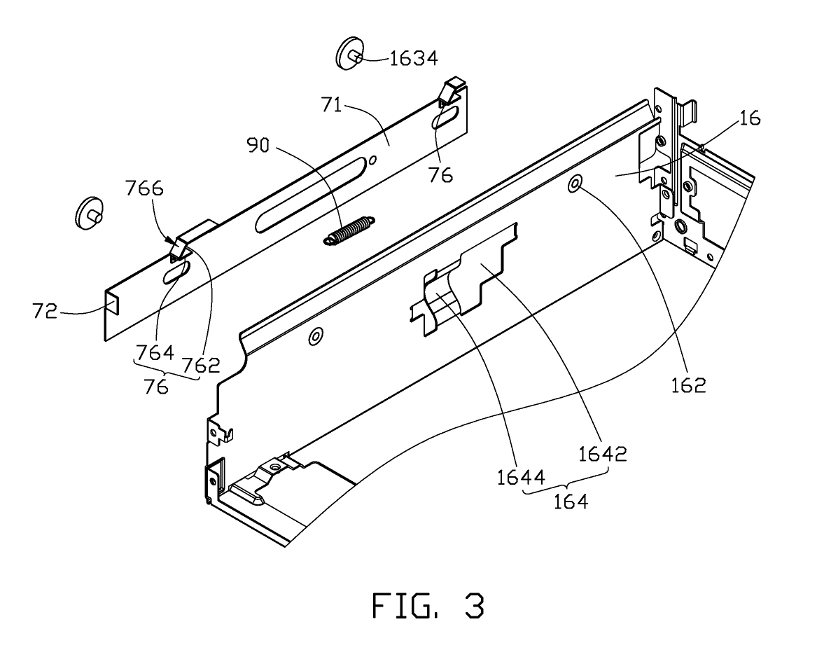

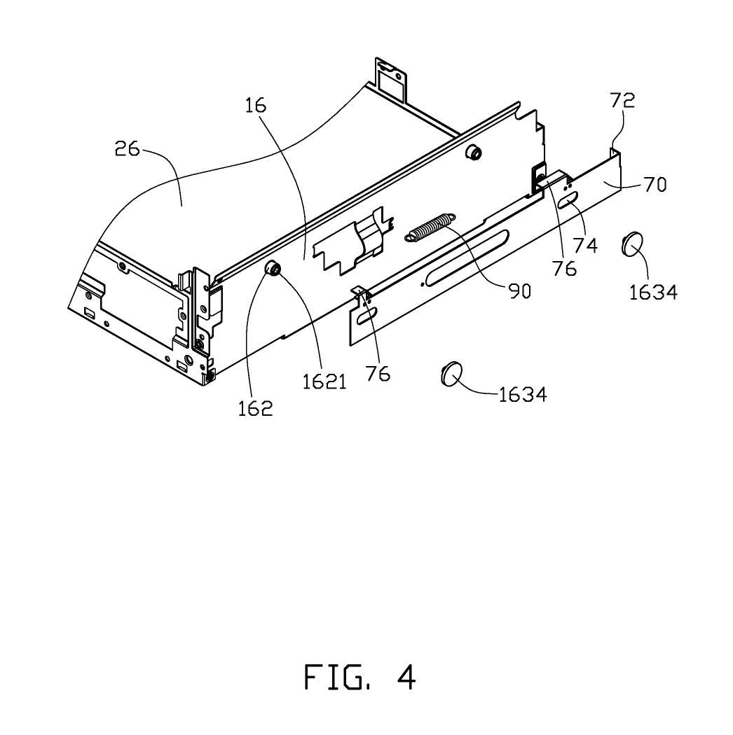

Referring to FIGS. 3 and 4 again, the sliding member 70 includes a substantially elongated base plate 71, a resisting portion 72 perpendicularly extending from one side of the base plate 71 for contacting the resisting member 59. Two sliding holes 74 slidably receive the corresponding guiding post 162, and two latching portions 76 engage with the second hooks 34, respectively. Each latching portion 76 includes an inclined plate 762 which has an inclined surface 766, and a resisting plate 766. One end of the inclined plate 762 is connected to the base plate 71, and the resisting plate 766 extends from the other end of the inclined plate 762. The resisting portion 72, the sliding holes 74, and the latching portions 76 can be integrally formed by stamping, thus facilitating the manufacturing of the sliding member 70.

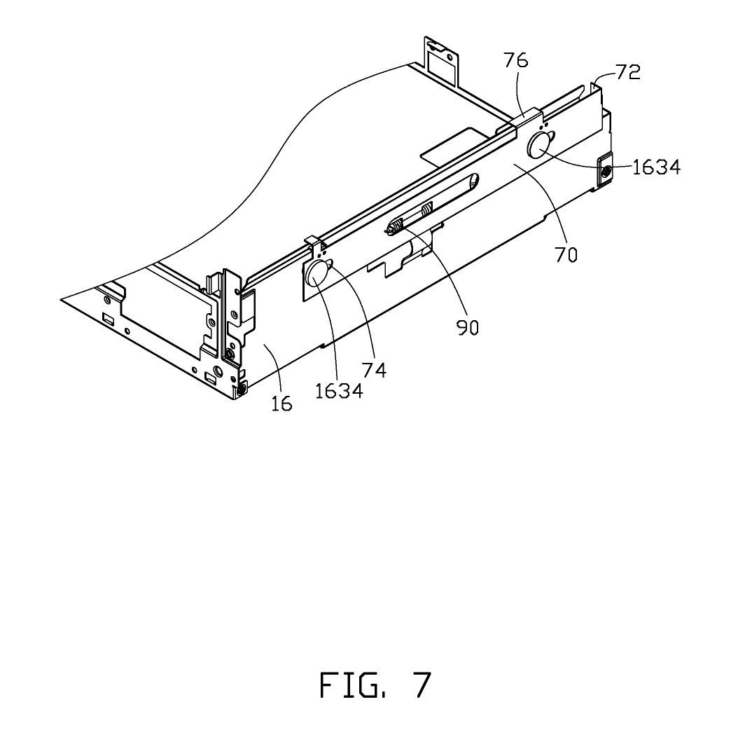

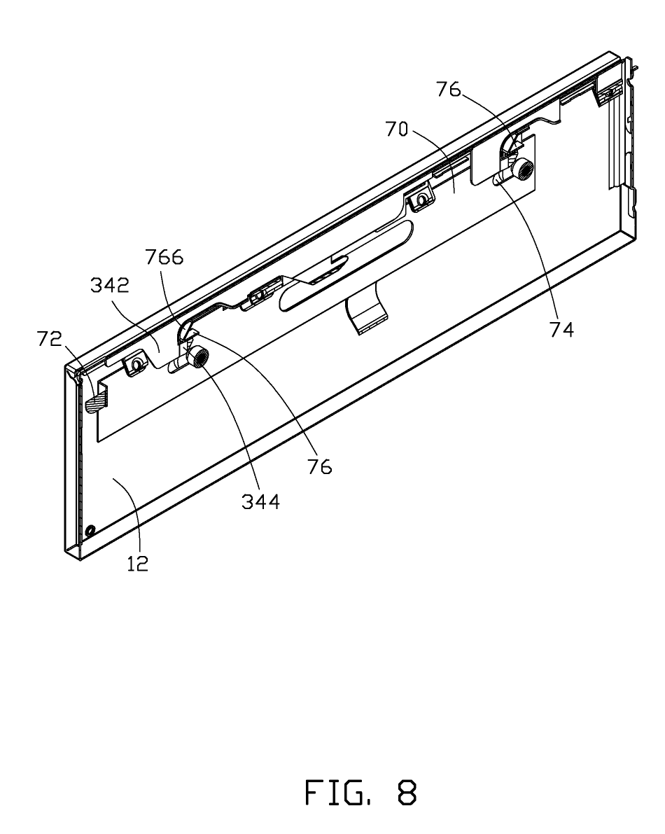

Referring to FIGS. 7 and 8 again, the sliding member 70 is mounted between the first sidewall 16 and the first assembly plate 12. The two guiding posts 162 of the first side plate 16 are received in the two sliding holes 74, respectively. The bolts 1634 are received in the corresponding sliding holes 74 and threaded holes 1621, thus connecting the sliding member 70 to the first sidewall 16.

The elastic member 90 is located between the sliding member 70 and the first sidewall 16. In one embodiment, the elastic member 90 is a compression spring, and is received in the guard 164. Two ends of the elastic member 90 are respectively fixed to the sliding member 70 and the first sidewall 16.

In use, to latch the cover 30 to the main body 10, the first hooks 32 of the cover 30 are received in the corresponding latching holes 181, thus the cover 30 is capable of rotating around the first hooks 32. When an external force is placed on the cover 30 to rotate the cover 30 to a predetermined position, the hooking portions 344 of the second hooks 34 attach and abut the inclined surface 766, thus moving the sliding member 70 along the sliding hole 74. At the same time, the elastic member 90 is deformed. When the hooking portion 344 is moved to the bottom of the latching portion 76, the elastic member 90 gradually restores to an original condition and resiliently pulls the sliding member 70, thus the inclined surface 766 is capable of sliding along the latitudinal direction so as to attach the supporting portion 342. Therefore, the latching portion 76 engages into the second hook 34, thus latching the cover 30 to the main body 10.

To unlatch the cover 30 from the main body 10, the operating member 52 is rotated, and the pivot 54 and the resisting member 59 rotate together with the operating member 52. At the same time, the torsion spring 56 is deformed, thus generating a restoring force. During the rotation of the operating member 52, the resisting members 59 abut and move the sliding member 70 in the latitudinal direction, until the latching portion 76 detaches from the second hooks 34, thus unlatching the cover 30. At the same time, the sliding member 70 is restored to its original state via the elastic member 90. When the external force is withdrawn, the operating member 52 is capable of restoring to an original state via the torsion spring 56, thus facilitating the unlatching operation. Then, by further rotating the cover 30 around the first hooks 32, the cover 30 can be detached from the main body 10.

It should be understood that the number of the second hooks 34 and the corresponding latching portions 76 may vary.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A computer enclosure comprising:
a main body having a plurality of walls and defining an opening in a side thereof, and at least one of the plurality of walls defining a plurality of first latching holes;
a cover detachably fixed to the main body for shielding the opening, the cover comprising a plurality of first hooks for engaging in the corresponding first latching holes, and at least one second hook;
a sliding member slidable relative to one of the walls, the sliding member comprising at least one latching portion for engaging with the at least one second hook correspondingly;
a rotating assembly mounted on the cover, the rotating assembly comprising:
a pivot rotatable relative to the cover; and
a resisting member securely mounted around the pivot for moving the sliding member along a predetermined direction; and
an elastic member connecting the sliding member and the main body for latching the at least one latching portions into the at least one second hook correspondingly; wherein when the pivot is rotated relative to the cover, the resisting member moves the sliding member relative to the main body to a predetermined position to detach the at least one latching portion from the at least one second hook, and the sliding member is restored to an original position via the elastic member.

2. The computer enclosure of claim 1, wherein the main body comprises a guiding post, and the sliding member defines a sliding hole for slidably receiving the guiding post.

3. The computer enclosure of claim 2, wherein the guiding post defines a threaded hole, and a bolt is received in the sliding hole and the threaded hole to connect the sliding member and the main body.

4. The computer enclosure of claim 1, wherein the plurality of first hooks and the at least one second hook are located on opposite sides of the cover.

5. The computer enclosure of claim 1, wherein the cover defines a receiving portion for receiving the rotating assembly.

6. The computer enclosure of claim 1, wherein each of the at least one second hook comprises a support portion and a hooking portion inward extending from the support portion, the hooking portion comprises an inclined abutting surface for contacting the sliding member.

7. The computer enclosure of claim 1, wherein the rotating assembly further comprises an operating member securely mounted around the pivot.

8. The computer enclosure of claim 7, wherein the rotating assembly further comprises a torsion spring for restoring the operating member to an original position.

9. The computer enclosure of claim 8, wherein the operating member comprises two deformed flanges formed on opposite sides thereof, and the torsion spring is located between the two deformed flanges.

10. The computer enclosure of claim 7, wherein the rotating assembly further comprising two clips securely mounted around the pivot to prevent the pivot from falling off.

11. The computer enclosure of claim 2, wherein the sliding member further comprising a base plate, a resisting portion perpendicularly extended from one side of the base plate for contacting the resisting member of the rotating assembly.

12. The computer enclosure of claim 11, wherein the resisting portion, the sliding holes, and the at least one latching portion are integrally formed by stamping.

13. The computer enclosure of claim 1, wherein the main body comprises a first sidewall, a second sidewall opposite to the first sidewall, a third sidewall, a fourth sidewall opposite to the third sidewall, and a bottom wall; the first sidewall, the second sidewall, the third sidewall, the fourth sidewall, and the bottom wall cooperatively define the opening.

14. The computer enclosure of claim 1, wherein the main body further comprises a first assembly plate mounted on the outside of the first sidewall, and a second assembly plate mounted on the outside of the second sidewall, and the sliding member located between the first sidewall and the first assembly plate.

15. A computer enclosure comprising:
a main body comprising a first sidewall and a second sidewall opposite to the first sidewall and defining an opening in a side thereof, and the first sidewall comprising a guiding post, and the second sidewall defining a plurality of first latching holes;
a cover detachably fixed to the main body for shielding the opening, the cover comprising a plurality of first hooks for engaging in the corresponding first latching holes, and at least one second hook;
a sliding member comprising a sliding hole for slidably receiving the guiding post, and at least one latching portion for engaging with the at least one second hook correspondingly;
a rotating assembly mounted on the cover, the rotating assembly comprising:
a pivot rotatable relative to the cover; and
a resisting member securely mounted around the pivot to move the sliding member along a predetermined direction; and
an elastic member connecting the sliding member and the first sidewall for latching the at least one latching portion into the at least one second hook correspondingly; wherein when the pivot is rotated relative to the cover, the resisting member moves the sliding member relative to the main body to a predetermined position to detach the at least one latching portion from the at least one second hook, and the sliding member is restored to an original position via the elastic member.
